(19) United States
(12) Patent Application Publication
(10) Pub. No.: US 2005/0106868 A1
(43) Pub. Date: May 19, 2005

(54) Etching method

(76) Inventors: Asao Yamashita, Yamanashi (JP); Fumihiko Higuchi, Yamanashi (JP); Takashi Enomoto, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/502,853

(22) PCT Filed: Jan. 31, 2003
(86) PCT No.: PCT/JP03/00998

(30) Foreign Application Priority Data
Jan. 1, 2002 (JP) 2002-26015

(51) Int. Cl. H01L 21/302; H01L 21/461

(52) U.S. Cl. 438/689

(57) ABSTRACT

An etching method for plasma etching a polysilicon film layer on a gate oxide film formed on a silicon substrate by introducing a processing gas into an airtight processing chamber comprises a main etching step for etching, by applying high frequency powers to the upper and the lower electrode, the polysilicon film in a depth direction of openings of a mask pattern serving as a mask, and an overetching step for removing, after the main etching step, residual parts of the polysilicon film, wherein in the middle of the main etching step, the high frequency power applied to the upper electrode is lowered down to a specific power level or lower, and the polysilicon film is etched until a part of the gate oxide film is exposed. Anisotropy in the profile can be improved while enhancing the selectivity of etching, and total etching rate can be prevented from being lowered.

### FIELD OF THE INVENTION

The present invention relates to an etching method using a plasma.

### BACKGROUND OF THE INVENTION

In a course of constructing MOS structures, such as memories and logics and so forth, on a substrate to be processed, there is conducted an etching on a silicon-based semiconductor film layer, such as a silicon oxide film and a polycrystalline silicon film. For example, in a case of processing a gate electrode on a substrate to be processed, there is executed a process to etch a layered structure, wherein a polysilicon film is deposited on a gate oxide film by a method such as CVD (chemical vapor deposition), wherein the polysilicon film is a polycrystalline silicon film, and the gate oxide film is a silicon oxide base film formed as an insulating film layer on the substrate to be processed.

As a plasma processing apparatus for the above etching, there is a plasma processing apparatus provided with an upper and a lower electrode facing each other in an airtight processing chamber and allowing high frequency powers to be applied to the upper and the lower electrode.

In case that the gate electrode is processed by using the plasma processing apparatus, when the polysilicon film of the above layered structure is etched by using a mask pattern such as an oxide film, it is processed by a plasma by introducing a processing gas, such as Cl₂, HBr, and O₂, into the processing vessel. At this time, for the purpose of increasing an etching rate and the like, the high frequency powers are applied to the upper and the lower electrode, and residual parts thereof are over-etched after etching is performed until the gate oxide base film is exposed.

Integration of a semiconductor device has lately been significantly improved, and thus, further size reduction of various elements formed on the substrate to be processed has become one of the most important technical requirements to be taken into consideration. In order to reduce a size of an element and the like, extensive research have been carried on to further reduce a thickness of the gate oxide film used as a base film in the course of processing the gate electrode, for example.

However, the conventional plasma etching process described above is problematic in that since the upper and the lower electrode are prepared in the processing chamber of the plasma processing apparatus to increase the total etching rate and the like and the high frequency powers are applied thereto to realize that goal, selectivity of the polycrystalline silicon film to the gate oxide film is reduced, and consequently, the gate oxide film acting as the base film may be undesirably etched as it becomes thinner.

Meanwhile, in order to improve the selectivity of a polycrystalline silicon film to a gate oxide film, it may be preferable to install only a lower electrode in a processing chamber of a plasma processing apparatus and to conduct etching by applying a high frequency power only to the lower electrode. However, the etching by applying a high frequency only to the lower electrode is disadvantageous in that an etching rate is reduced.

Further, when the selectivity is increased, it is apt to be in a so-called deposition-rich state, in which a large amount of reaction products, such as SiBr, is generated in the course of etching. And in consequence, the reaction products are deposited, resulting in a formation of a large tapered part around a lower part of a gate. Accordingly, it is difficult to realize an anisotropic etching profile. As described above, the etching profile perpendicular to a surface of the substrate to be processed and the selectivity are in a trade-off relation.

To ameliorate such problems, the present invention has been developed to provide an etching method, whereby anisotropy in the profile can be improved (for example, acquiring a profile with a pattern perpendicular to a surface of a substrate to be processed) while enhancing the selectivity of etching at the same time and total etching rate can be prevented from being lowered.

### SUMMARY OF THE INVENTION

In accordance with the present invention to dissolve the above problems, there is provided a new and improved method for plasma etching a film layer to be processed on an insulating film layer formed on an object to be processed by introducing a processing gas into an airtight processing chamber by using a plasma processing apparatus provided with an upper and a lower electrode facing each other in the processing chamber and allowing high frequency powers to be applied to the upper and the lower electrode.

In accordance with the present invention, while plasma etching the film layer to be processed by applying the high frequency powers to the upper and the lower electrode, a high frequency power applied to the upper electrode is set to be a specific power level or lower.

The film layer to be processed is preferably positioned on an insulating film layer formed on the object to be processed. And, the high frequency power applied to the upper electrode is preferably set to be 0.16 W/cm² or lower (i.e. about 50 W or lower in the case of a wafer with a diameter of 200 mm), and more preferably 0 W/cm² in the course of the first etching step. With this, a high frequency power applied to the lower electrode is preferably set to be 0.4 W/cm² or lower (i.e. about 150 W or lower in the case of a wafer with a diameter of 200 mm).

In accordance with an aspect of the present invention, the etching method includes a main etching step for etching the film layer to be processed in a depth direction of openings of a mask pattern serving as a mask by applying high frequency powers to the upper and the lower electrode; and an overetching step for removing, after the main etching step, residual parts of the film layer to be processed. And, in the middle of the main etching step, the high frequency power applied to the upper electrode is lowered down to the specific power level or lower and the film layer to be processed is etched until a part of the insulating film layer is exposed.

Here, the main etching step preferably includes a first main etching step for etching the film layer to be processed down to a level where the insulating film layer is not exposed; and a second main etching step for etching, after the first main etching step, the film layer to be processed until the part of the insulating film layer is exposed with the high frequency power applied to the upper electrode lowered down to the specific power level or lower, the specific power level being lower than a power level of the first main etching step.

In addition, the high frequency power applied to the upper electrode is preferably set to be 0.16 W/cm² or lower, and more preferably 0 W/cm² in the second main etching step. With this, the high frequency power applied to the lower electrode is preferably set to be 0.4 W/cm² or lower.

In accordance with another aspect of the present invention, the etching method includes a main etching step for etching, by applying high frequency powers to the upper and the lower electrode, the film layer to be processed in a depth direction of openings of a mask pattern serving as a mask until a part of the insulating film layer is exposed; and an overetching step for removing, after the main etching step, residual parts of the film layer to be processed, wherein during the overetching step in which the residual parts of the film layer to be processed are etched, the high frequency power applied to the upper electrode is lowered down to the specific power level or lower.

Here, the high frequency power applied to the upper electrode is preferably set to be 0.16 W/cm² or lower, and more preferably 0 W/cm² during the overetching step. With this, the high frequency power applied to the lower electrode is preferably set to be 0.4 W/cm² or lower.

In accordance with another aspect of the present invention, the etching method includes a main etching step for etching, by applying high frequency powers to the upper and the lower electrode, the film layer to be processed in a depth direction of openings of a mask pattern serving as a mask until a part of the insulating film layer is exposed; and an overetching step for removing, after the main etching step, residual parts of the film layer to be processed, wherein in any one or both of the main etching step and the overetching step, the film layer to be processed is etched with the high frequency power applied to the upper electrode lowered down to the specific power level or lower.

In accordance with another aspect of the present invention, the etching method includes a first main etching step for etching the film layer to be processed in a depth direction of openings of a mask pattern serving as a mask by applying the high frequency powers to the upper and the lower electrode to a level where the insulating film layer is not exposed; a second main etching step for etching, after the first main etching step, the film layer to be processed until a part of the insulating film layer is exposed; and an overetching step for removing residual parts of the film layer to be processed, wherein throughout the second main etching step to the overetching step, the high frequency power applied to the upper electrode is lowered down to the specific power level or lower to etch the film layer to be processed.

Here, the high frequency power applied to the upper electrode is preferably set to be 0.16 W/cm² or lower, and more preferably 0 W/cm² throughout the second main etching step to the overetching step. With this, the high frequency power applied to the lower electrode is preferably set to be 0.4 W/cm² or lower.

In accordance with the present invention, if the high frequency power applied to the upper electrode is set to be a specific power level or lower, for example, 0.16 W/cm² or lower, in any one or both of the main etching step and the overetching step, reaction products, generated in the course of etching, are attached to the upper electrode. More preferably, if the high frequency power is set to 0 W/cm², more reaction products are attached to the upper electrode.

Moreover, if the high frequency power is 0.16 W/cm² or lower, a sheath voltage is very low even though it is generated at the upper electrode, and if the high frequency power is 0 W/cm², no sheath voltage is generated at the upper electrode, thus preventing the reaction products attached to the upper electrode from being deposited on the wafer to the utmost. Thereby, it is possible to realize a deposition-less state, in which the reaction products generated in the course of etching are not deposited on the wafer to the utmost.

For this reason, a selectivity of the film layer to be processed, such as a polysilicon film layer, to the insulating film layer, such as a gate oxide film, (a ratio of an etching rate of the objective film to an etching rate of the insulating film layer) can be improved, and the reaction products generated in the course of etching can be prevented from being deposited on the wafer to the utmost (e.g., acquiring a profile with a pattern perpendicular to a surface of the substrate to be processed). Hence, the gate can have a profile without a tapered portion formed around a lower part thereof to the utmost. Therefore, the anisotropy in the profile can be improved while enhancing the selectivity. Furthermore, since the high frequency powers are applied to the upper and the lower electrode to an etching level where the insulating film layer is not exposed in the first main etching step, the total etching rate can be prevented from being lowered.

Meanwhile, in the specification, 1 mTorr is (10⁻³×101325/760) Pa, and 1 sccm is (10⁻⁶/60) m³/sec.

### BRIEF DESCRIPTION OF THE DRAWINGS

FIG. 1 schematically illustrates an etching apparatus, which is used to realize an etching method in accordance with the first embodiment of the present invention;

FIG. 2 provides a schematic diagram to explain a process of the etching method in accordance with the first embodiment of the present invention;

FIG. 3 provides a schematic diagram to explain the process of the etching method in accordance with the first embodiment of the present invention;

FIG. 4 describes an example configuration of a detecting unit in accordance with the first embodiment of the present invention, by which an end point of a first main etching step is determined;

FIG. 5 depicts an operation while etching a polysilicon film in accordance with the first embodiment of the present invention;

FIG. 6 shows a relation between an intensity of interference light and an etching time;

FIG. 7 illustrates an etched object in case when the high frequency power of 300 W is applied to an upper electrode during a second main etching step;

FIG. 8 illustrates an etched object in case when the high frequency power is not applied to the upper electrode during the second main etching step;

FIG. 9 provides a schematic diagram to explain a process of an etching method in accordance with the second embodiment of the present invention;

FIG. 10 provides a schematic diagram to explain the process of the etching method in accordance with the second embodiment of the present invention;

FIG. 11 provides a schematic diagram explaining the process of the etching method in accordance with the second embodiment of the present invention;

FIG. 12 illustrates an etched object in case when the high frequency power is not applied to the upper electrode during an overetching step; and

FIG. 13 illustrates an etched object in case when the high frequency power is not applied to the upper electrode throughout a middle of a first main etching step to an overetching step in accordance with the third embodiment of the present invention.

### DETAILED DESCRIPTION OF THE PREFERRED EMBODIMENTS

The preferred embodiments are now described in detail with reference to the drawings, in which same reference numerals are used to designate elements with substantially same function and duplicated descriptions are omitted.

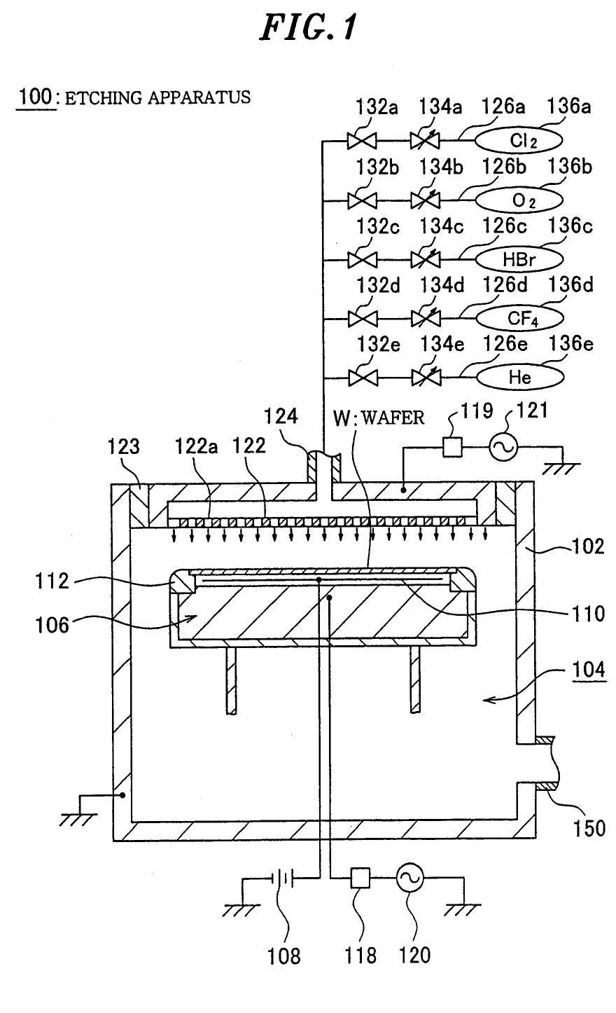

FIG. 1 schematically illustrates a parallel plate plasma etching apparatus which is an example etching apparatus used to realize an etching method in accordance with the first embodiment of the present invention.

The etching apparatus 100 includes a processing chamber 104 defined by a safely earthed processing vessel 102, and a lower electrode 106 included in a suscepter is installed in the processing chamber 104, wherein the suscepter can be vertically moved up and down freely. An electrostatic chuck 110 connected to a high voltage DC power supply 108 is provided at an upper part of the lower electrode 106, and an object to be processed, for example a semiconductor wafer (hereinafter, referred to as “wafer”) (W), is mounted on the electrostatic chuck 110. And, an insulating focus ring 112 is placed around the wafer (W) mounted on the lower electrode 106, which is connected through a matching unit 118 to a second high frequency power supply 120.

And, an upper electrode 122 having a plurality of gas supply openings 122a is provided at the top of the processing chamber 104 in such a way to face the lower electrode 106. An insulator 123 is interposed between the upper electrode 122 and the processing vessel 102 to electrically isolate the upper electrode 122 from the processing vessel 102. And, the upper electrode 122 is connected through a matching unit 119 to a first high frequency power supply 121 generating a high frequency power to form a plasma.

And, a first high frequency power of a frequency equal to or higher than 30 MHz, and preferably 60 MHz, is applied from the first high frequency power supply 121 to the upper electrode 122. And, a second high frequency power that is of a lower frequency than the first high frequency power generated from the first high frequency power supply 120, for example 1-30 MHz, and preferably 13.56 MHz, is applied to the lower electrode 106. The first and the second high frequency power respectively applied to the lower and the upper electrode 106, 122 can be varied in a range from 0 W to 650 W.

A gas supply line 124 communicates with the gas supply openings 122a, and the gas supply line 124 is connected to a processing gas supply system 126a for supplying Cl₂, a processing gas supply system 126b for supplying O₂, a processing gas supply system 126c for supplying gas, containing at least H and Br, in detail HBr, a processing gas supply system 126d for supplying gas, containing at least C and F, in detail CF₄, and a processing gas supply system 126e for supplying He.

The processing gas supply systems 126a, 126b, 126c, 126d, and 126e are coupled with a Cl₂ gas supply source 136a, an O₂ gas supply source 136b, an HBr gas supply source 136c, a CF₄ gas supply source 136d, and a He gas supply source 136e, respectively, via opening/closing valves 132a, 132b, 132c, 132d, and 132e, respectively, and flow rate control valves 134a, 134b, 134c, 134d, and 134e, respectively.

And, a gas exhaust line 150 communicating with a vacuum exhaust unit (not shown) is formed at a lower part of the processing vessel 102, and an inner space of the processing chamber 104 is maintained under reduced pressure by the vacuum exhaust unit.

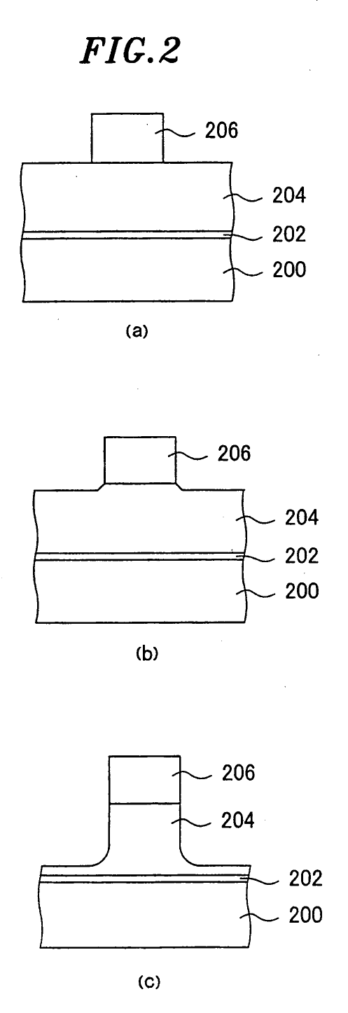

Hereinafter, a description will be given for an etching method using the above etching device in accordance with the first embodiment of the present invention, referring to FIGS. 2-8. With reference to FIG. 2(a), there is illustrated a layered structure to be etched in accordance with the first embodiment of the present invention.

The layered structure is fabricated in accordance with the following procedure. A gate oxide film 202 (e.g. SiO₂ film) is formed as an insulating film on an object to be processed, for example, a silicon substrate 200 of a wafer with a diameter of 200 mm. A polysilicon film 204 as a polycrystalline silicon film is then deposited on an entire surface of the silicon substrate 200. Subsequently, by transcription of a pattern of a photoresist mask patterned by using a photolithography, a mask pattern of an oxide film 206, such as SiO₂, is formed on the polysilicon film 204.

And then, the layered structure as shown in FIG. 2(a) is etched by using the plasma processing apparatus. First, a native oxide film of an exposed portion of the polysilicon film 204 is etched to be removed by using a mixed gas that contains at least CF₄ and O₂ (BT (break through) etching step). The break through etching step is conducted under conditions that pressure in the processing vessel 102 is 10 mTorr, a gap between the upper and the lower electrode 122 and 106 is 140 mm, a flow rate ratio of CF₄ to O₂ (a flow rate of CF₄/a flow rate of O₂) is 134 sccm/26 sccm, a voltage applied to the electrostatic chuck for drawing the wafer is 2.5 kV, pressures of cooling gas applied to an edge and a center of a backside of the wafer are both 3 mTorr, temperatures of the lower and the upper electrode in the processing chamber 104 are 75° C. and 80° C., respectively, and a temperature of a sidewall of the processing chamber 104 is 60° C.

In this step, the high frequency powers applied to both the upper and the lower electrode 122, 106 are high. For example, the high frequency power applied to the upper electrode 122 is set to be 650 W, and the high frequency power applied to the lower electrode 106 is set to be 220 W. Thereby, the native oxide film on the exposed portion of the polysilicon film 204 is removed as shown in FIG. 2(b).

Next, there is conducted a main etching step wherein the polysilicon film layer 204 is etched in a depth direction of openings of a mask pattern. The main etching step may be classified into a first main etching step and a second main etching step.

In the main etching step, the polysilicon film 204 is etched in the depth direction of the openings of the mask pattern by using a mixed gas that contains at least HBr and O₂ as a processing gas to a level where the gate oxide film 202 is not exposed, for example, the polysilicon film 204 is etched by 85% of a total thickness of the polysilicon film 204 (ME1: the first main etching step). Since the gate oxide film 202 is not yet exposed in the first main etching step, it is etched under a condition suitable to increase an etching rate of the polysilicon film 204.

An example of a condition for the first main etching step is that pressure in the processing vessel 102 is 20 mTorr, the gap between the upper and the lower electrode 122 and 106 is 140 mm, a flow rate ratio of HBr to O₂ (a flow rate of HBr/a flow rate Of O₂) is 400 sccm/1 sccm, the voltage applied to the electrostatic chuck for drawing the wafer is 2.5 kV, pressures of the cooling gas applied to the edge and the and center of the backside of the wafer are both 3 mTorr, the temperatures of the lower and the upper electrode in the processing chamber 104 are 75° C. and 80° C., respectively, and the temperature of the sidewall of the processing chamber 104 is 60° C.

In this step, the high frequency powers applied to the upper and the lower electrode 122, 106 are high. For example, the high frequency power applied to the upper electrode 122 is set to be 200 W, and the high frequency power applied to the lower electrode 106 is set to be 100 W. Thereby, the portion of the polysilicon film 204 is etched in the depth direction of the openings of the mask pattern by about 85% of an initial thickness of the polysilicon film 204, as shown in FIG. 2(c).

An end point of the first main etching step may be determined by various procedures. For example, there is measured a time required to etch a dummy wafer by a desired depth (e.g. 85%), and the polysilicon film 204 is then subjected to the first main etching step for the measured time. Thereby, the polysilicon film 204 can be etched to a desired depth.

Alternatively, the end point of the first main etching step may be determined by measuring a thickness between an upper surface of the gate oxide film 202 (an interface between the polysilicon film 204 and the gate oxide film 202) and an upper surface of an etched portion of the polysilicon film 204. When the etching is conducted for a etching time, the etching is finished after the polysilicon film 204 has been etched for the time. Accordingly, if there is an error or a deviation in a thickness of the polysilicon film 204, the thickness between the upper surface of the gate oxide film 202 and the upper surface of the etched portion of the polysilicon film 204 may not have the desired value after the completion of the etching. But, if the end point of the first main etching step is determined by measuring the thickness between the upper surface of the gate oxide film 202 and the upper surface of the etched portion of the polysilicon film 204, the polysilicon film 204 can be precisely etched to the desired depth even when there is an error or a deviation in the thickness of the polysilicon film 204.

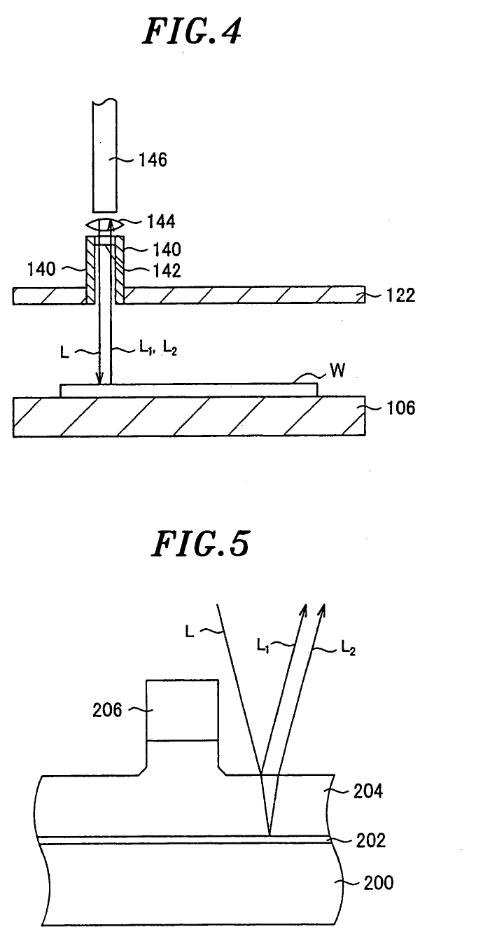

A description will be given for the determination of the end point of the first main etching step by measuring the thickness between the upper surface of the gate oxide film 202 and the upper surface of the etched portion of the polysilicon film 204, referring to FIGS. 4 to 6. With reference to FIG. 4, a cylindrical observation unit 140 is provided at the upper electrode in the processing chamber 104. Light is irradiated from a light source (not shown) through the observation unit 140 to a wafer (W) and interference light with a wavelength of the reflection light is simultaneously detected by using, for example, a polychromator (not shown). And, the end point is determined on the basis of an interference light variation.

In detail, the observation unit 140 is provided with a window 142 made of quartz or glass on the top thereof. And, the observation unit 140 is coupled with the light source and the polychromator, through a condensing lens 144 facing the window 142, by an optical fiber 146 and the like. The light source is exemplified by a xenon or tungsten lamp.

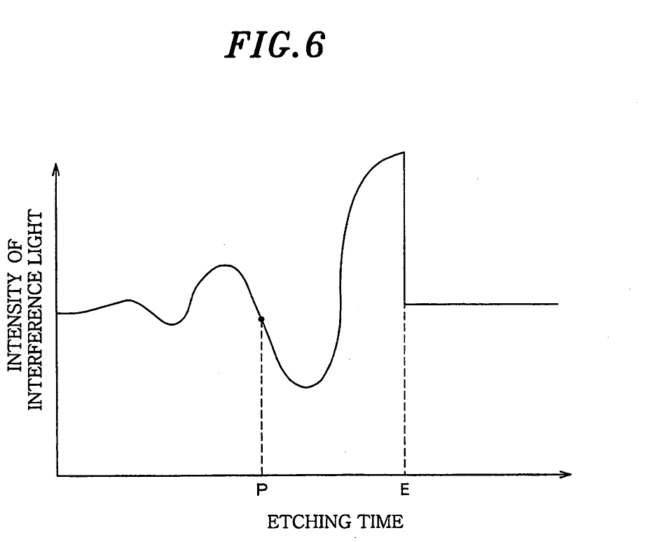

As shown in FIGS. 4 and 5, when white light (L) is irradiated from the light source, for example the xenon lamp, through the observation unit 140 to the wafer (W), a portion of the white light (L) is reflected by the upper surface of the polysilicon film 204 (reflection light (L1)). Further, the remaining portion of the white light (L) is transmitted through the polysilicon film 204 and reflected by the interface between the polysilicon film 204 and the gate oxide film 202 (reflection light (L2)). The reflected lights (L1, L2) are interfered with each other to form an interference light, and the interference light is transferred through the observation unit 140 and the optical fiber and the like to be detected by the polychromator.

The interference light formed by the reflected lights (L1, L2) is varied depending on the etching time of the polysilicon film 204, as shown in FIG. 6. FIG. 6 is a graph showing intensity of interference light per time as a function of the etching time for the polysilicon film 204. With reference to FIG. 6, the intensity of interference light fluctuates as the thickness of the polysilicon film 204 decreases; reaches highest intensity at the very time when the polysilicon film 204 is completely etched; and becomes constant thereafter. The time when the intensity of interference light reaches a constant value corresponds to a point E in time when the gate oxide film 202 begins to be exposed after the polysilicon film 204 is etched.

The end point of the first main etching step is supposed to be positioned prior to the point E. For this reason, the intensity of interference light at the time when the thickness between the upper surface of the gate oxide film 202 and the upper surface of the etched portion of the polysilicon film 204 becomes a desired value (e.g. the intensity of interference light at a point P in FIG. 6) is measured in advance by using the dummy wafer. And, when the intensity of the interference light reaches the desired value measured in advance in the course of monitoring the intensity of interference light, the first main etching step is stopped. In this way, the polysilicon film 204 is etched to the desired depth so as to secure the desired thickness between the upper surface of the gate oxide film 202 and the upper surface of the etched portion of the polysilicon film 204.

In accordance with the first embodiment of the present invention, the end point of the first main etching step corresponds to the point where the thickness between the upper surface of the gate oxide film 202 and the upper surface of the etched portion of the polysilicon film 204 is 30 nm, for example (the point P in FIG. 6, for example). 30 nm is about 15% of the initial thickness of the polysilicon film 204, and in other words, the first main etching step is finished when the polysilicon film 204 is etched by 85% of the initial thickness thereof.

By employing this method, since the end point of the first main etching step is determined by measuring the thickness between the upper surface of the gate oxide film 202 and the upper surface of the etched portion of the polysilicon film 204, the polysilicon film 204 can be precisely etched to the desired depth even though the polysilicon film 204 has a undesired thickness before it is etched.

The first main etching step is finished on the basis of the end point determined in the above procedures.

Subsequently, the polysilicon film 204 is etched by using the mixed gas, containing at least HBr, O₂, and He, as the processing gas until the gate oxide film 202 is exposed (ME2; second main etching step).

In the second main etching step, since the gate oxide film 202 begins to be exposed as the etching progresses, it is necessary to improve a selectivity of the polysilicon film 204 to the gate oxide film 202 (a ratio of an etching rate of the polysilicon film 204 to an etching rate of the gate oxide film 202) so as to prevent the gate oxide film from being damaged. For this purpose, the flow rate of O₂ or HBr is set to be relatively high.

However, when the flow rate of O₂ or HBr is relatively high, reaction products of an etching reaction of the polysilicon film 204 are generated in a large amount (deposition-rich state). The reaction products are deposited on the wafer to thereby form a tapered portion around a lower part of a gate, and thus, it is difficult to improve anisotropy in the profile. For this reason, in order to prevent the tapered portion from being formed around the lower part of the gate to the utmost while enhancing the selectivity, it is necessary to reduce the amount of the reaction products to the utmost to thereby result in a reduction of the reaction products deposited on the wafer.

As a result of repeated experiments, the present inventors have found that the selectivity of the polysilicon film 204 to the gate oxide film 202 (the ratio of the etching rate of the polysilicon film 204 to the etching rate of the gate oxide film 202) can be improved while reducing the amount of the reaction products to thereby reduce the reaction products deposited on the wafer to the utmost by setting the high frequency power applied to the upper electrode 122 to a specific power level or lower during the main etching step, i.e., after the completion of the first main etching step in the case of the first embodiment of the present invention.

When the high frequency power applied to the upper electrode 122 is set to the specific power level or lower, for example, about 50 W (0.16 W/cm²) or lower in the case of etching a wafer with a diameter of 200 mm, and preferably 0 W (0 W/cm²), the reaction products become adhered to the upper electrode 122. And, when the high frequency power is 50 W or lower, a sheath voltage is very low even when it is generated at the upper electrode 122, and when the high frequency power is 0 W, no effective sheath voltage is generated at the upper electrode 122, thus preventing the reaction products adhered to the upper electrode 122 from being deposited on the wafer to the utmost. Thereby, it is possible to realize a deposition-less state, in which the reaction products are not deposited on the wafer to the utmost.

Based on the above description, the second main etching step is conducted. An example of a condition for the second main etching step is that pressure in the processing vessel 102 is 20 mTorr, the gap between the upper and the lower electrode 122 and 106 is 140 mm, a flow rate ratio of HBr/O₂/He (a flow rate of HBr,/a flow rate of O₂/a flow rate of He) is 500 sccm/15 sccm/440 sccm, the voltage applied to the electrostatic chuck for drawing the wafer is 2.5 kV, pressures of the cooling gas applied to the edge and the center of the backside of the wafer are both 3 mTorr, the temperatures of the lower and the upper electrode in the processing chamber 104 are 75° C. and 80° C., respectively, and a temperature of the sidewall of the processing chamber 104 is 60° C.

Like the case of the first main etching step, the high frequency electrical power of 100 W is applied to the lower electrode 106. In contrast, the high frequency electrical power applied to the upper electrode 122 is reduced at a time to a value lower than that in the case of the first main etching step. For example, the high frequency power applied to the upper electrode 122 is set such that the reaction products are not deposited on the wafer. In detail, it is set to preferably 0.16 W/cm² or lower (i.e. about 50 W or below in the case of etching the wafer with the diameter of 200 mm), and more preferably 0 W/cm². In such a case, if the high frequency power applied to the lower electrode 106 is set to be too high, the oxide film may be damaged. For this reason, it is preferable that the high frequency power applied to the lower electrode 106 is set to 0.4 W/cm² or lower (i.e. about 150 W or below in the case of etching the wafer with the diameter of 200 mm).

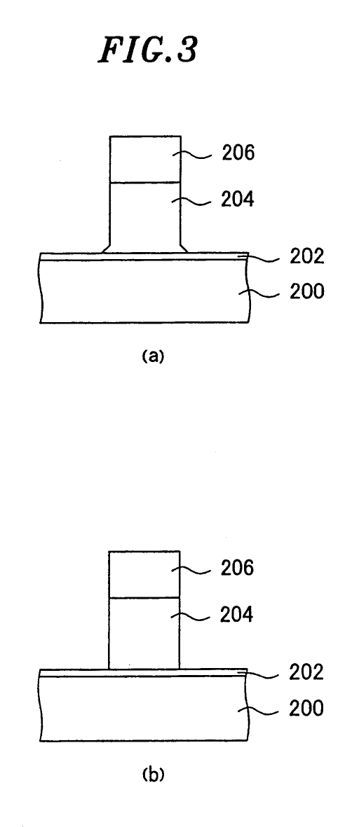

In this way, it is possible to further etch the remaining parts of the polysilicon film 204 so that a tapered portion is further prevented from being formed around the lower part of the gate as shown in FIG. 3(a). Therefore, the anisotropy in the profile of the gate is improved while enhancing the selectivity.

An end point of the second main etching step may be determined on the basis of the interference light variation of reflection light after light is irradiated from the light source through the observation unit 140 to the wafer. In detail, the second main etching step may be finished at the point E where the intensity of interference light starts being constant in FIG. 6.

Alternatively, the end point of the second main etching step may be determined on the basis of a variation in an emission spectrum of a plasma excited in the processing chamber 104. In detail, a plasma light detection window (not shown) made of quartz is provided on the sidewall of the processing chamber 104, and an emission spectrum is transmitted from the processing chamber 104 through the plasma light detection window to a light receiving unit of an end point detector (not shown) outside the processing chamber 104. In the end point detector, the end point of the second main etching step is determined based on the variation in the emission spectrum transmitted from the light receiving unit thereof.

In detail, during the second main etching step, the plasma is excited in the processing chamber 104, and the wafer (W) is etched by the plasma. Here, the emission spectrum of the plasma is varied during the course of etching the wafer (W). Hence, it is observed in advance how the emission spectrum is varied at an end point of the second main etching step, and the end point of the second main etching step when actually etching a wafer W is determined as a point where the emission spectrum of the plasma varies in the same way as it was observed in advance. The second main etching step of the wafer (W) is finished at the determined end point.

Subsequently, an overetching step is conducted to remove residual parts of the polysilicon film layer 204. In this step, the residual parts (e.g. the tapered portion around the lower part of the gate) of the polysilicon film 204 are etched by using the mixed gas containing at least HBr and O₂ as the processing gas (OE; overetching step).

An example of a condition for the overetching step is that pressure in the processing vessel 102 is 150 mTorr, the gap between the upper and the lower electrode 122 and 106 is 140 mm, a flow rate ratio of HBr to O₂ (a flow rate of HBr/a flow rate of O₂) is 1000 sccm/4 sccm, the voltage applied to the electrostatic chuck for drawing the wafer is 2.5 kV, pressures of the cooling gas applied to the edge and the center of the backside of the wafer are both 10 mTorr, the temperatures of the lower and the upper electrode in the processing chamber 104 are 75° C. and 80° C., respectively, and the temperature of the sidewall of the processing chamber 104 is 60° C.

In this step, the high frequency powers are applied to the upper and the lower electrode 122, 106 so as to increase an etching rate of the polysilicon film 204. For example, the high frequency power applied to the upper electrode 122 is set to be 650 W, and the high frequency power applied to the lower electrode 106 is set to be 200 W. In this case, since pressure in the processing vessel 102 is relatively high, for example, 150 mTorr, the gate oxide film is not damaged since ions of a plasma are scattered even when the high frequency power applied to the upper electrode 122 is a relatively high 650 W. By this step, residual parts (tapered portion around the lower part of the gate) of the polysilicon film 204 are fully etched and a gate electrode with an excellent anisotropic profile thereof (e.g. the gate electrode with a pattern having a wall perpendicular to the upper surface of the gate oxide film) is formed, as shown in FIG. 3(b).

In the case of etching the polysilicon film to form the above gate, if the layered structure includes the gate oxide film 202 of a thickness of 15 Å, the polysilicon film 204 of a thickness of 150 nm, and the oxide film 206 of a thickness of 50 nm used as a mask, the following condition is preferably required: the etching rate is 1500 Å/min or more, uniformity is within ±3.0%, an angle of a lower wall of the pattern of the gate to the upper surface of the gate oxide film is 90 degrees, and the gate oxide film is not damaged (no oxide break phenomenon occurs). In the present invention, the above-mentioned conditions can be satisfied.

Hereinafter, a description will be given for a comparison of two cases: in one case, the high frequency power of 300 W is applied to the upper electrode 122 in the second main etching step, and in the other case, the second main etching step is conducted without the high frequency power being applied to the upper electrode 122.

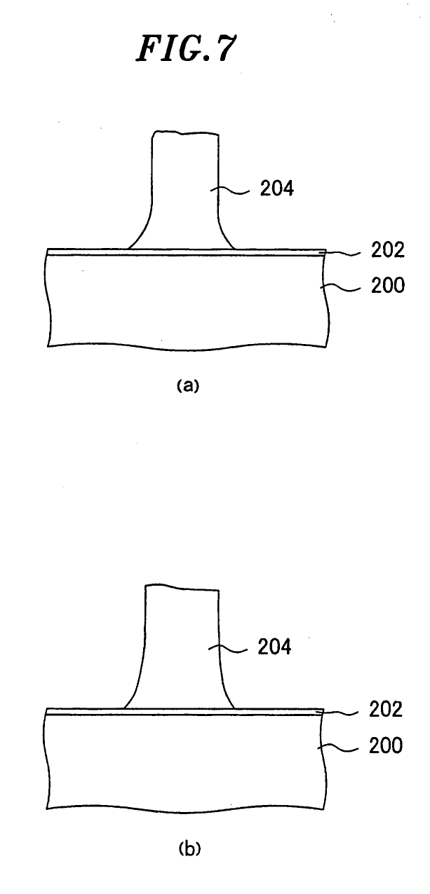

FIG. 7 illustrates the etched object for the case when it is etched while the high frequency power of 300 W is applied to the upper electrode 122 during the first and second main etching steps, wherein FIG. 7(a) illustrates the etched object when the gate is formed on the center of the wafer and FIG. 7(b) illustrates the etched object when the gate is formed on the edge of the wafer. In this case, tapered portions remain around lower parts of the gates formed on the center and edge of the wafer.

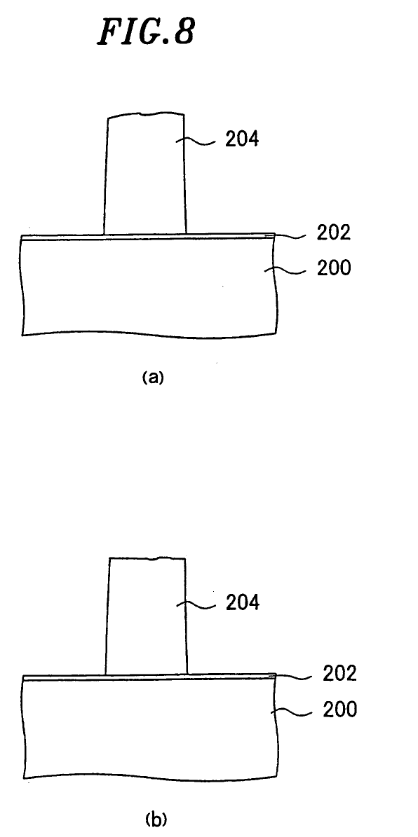

On the other hand, FIG. 8 illustrates the etched object for the case when it is etched while the high frequency power of 0 W is applied to the upper electrode 122, that is to say, while the high frequency power is not applied to the upper electrode 122 in the main etching step. At this time, FIG. 8(a) illustrates the etched object when the gate is formed on the center of the wafer, and FIG. 8(b) illustrates the etched object when the gate is formed on the edge of the wafer. In this case, there are no tapered portions of the polysilicon film 204 remained around lower parts of the gates formed on the center and edge of the wafer unlike the case of FIG. 7.

As described above, after the first main etching step, the high frequency power applied to the upper electrode 122 is reduced at a time to 50 W or lower, preferably 0 W, lower than the high frequency power of the first main etching step. In this way, the selectivity of the polysilicon film 204 to the gate oxide film 202 (the ratio of the etching rate of the polysilicon film 204 to the etching rate of the gate oxide film 202) can be increased while preventing the reaction products, generated in the course of etching the polysilicon film 204, from being deposited on the wafer to the utmost (deposition-less state). Hence, the gate is formed to the best on the wafer without the tapered portion of the polysilicon film 204 remaining around the lower part thereof. Therefore, the selectivity as well as the anisotropic profile of the gate is improved at the same time in accordance with the first embodiment of the present invention.

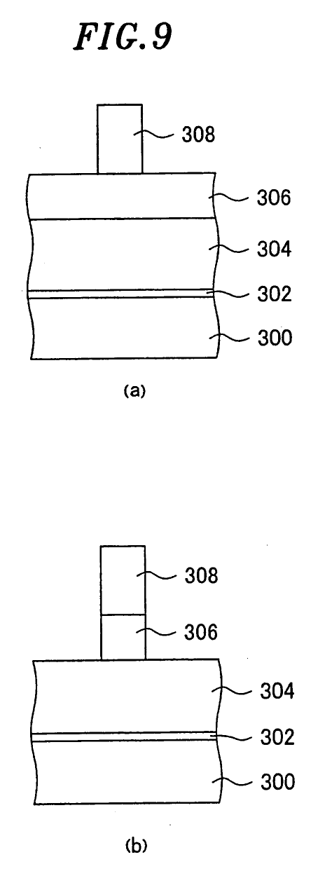

Hereinafter, a description will be given for the second embodiment of the present invention, referring to the drawings. Unlike the first embodiment in which the high frequency power applied to the upper electrode 122 is reduced to a specific power level in the middle of the main etching step, the high frequency power applied to the upper electrode 122 is reduced to a specific power level during the overetching step, istead, in the second embodiment. FIGS. 9 to 12 illustrate the etching of the wafer in accordance with the second embodiment.

With reference to FIG. 9(a), there is illustrated a detailed example of a layered structure which is to be etched in accordance with the second embodiment. The layered structure for the second embodiment is fabricated in accordance with the following procedure. A gate oxide film 302 is formed as an insulating film layer on an object to be processed, for example, a silicon substrate 300 of a wafer with a diameter of 200 mm. A polycrystalline silicon film, that is, a polysilicon film 304 is then deposited on an entire surface of the silicon substrate 300. Subsequently, an antireflection film 306 is formed on the polysilicon film 304 by using a photolithography and the like, and a mask pattern such as a KrF resist film (PR) 308 is formed.

And then, the layered structure as shown in FIG. 9(a) is etched by using the plasma processing apparatus of the first embodiment. Firstly, a portion of the antireflection film 306 corresponding to the mask pattern of the resist film 308 is etched by using a mixed gas containing at least Cl₂ and O₂ (ARC: antireflection coating removal etching). An example of a condition for the ARC etching step is that pressure in the processing vessel 102 is 5 mTorr, the gap between the upper and the lower electrode 122 and 106 is 80 mm, a flow rate ratio of Cl₂ to O₂ (a flow rate of Cl₂/a flow rate of O₂) is 10 sccm/30 sccm, the voltage applied to the electrostatic chuck for drawing the wafer is 1.5 kV, pressures of the cooling gas applied to an edge and a center of the backside of the wafer are both 3 mTorr, temperatures of the lower and the upper electrode in the processing chamber 104 are 70° C. and 80° C., respectively, and the temperature of the sidewall of the processing chamber 104 is 60C. And, the high frequency power applied to the upper electrode 122 is set to be 300 W, the high frequency power applied to the lower electrode 106 is set to be 30 W, and the layered structure is treated by a plasma for about 100 sec. Thereby, the portion of the antireflection film 306 corresponding to the mask pattern of the resist film 308 is removed as shown in FIG. 9(b).

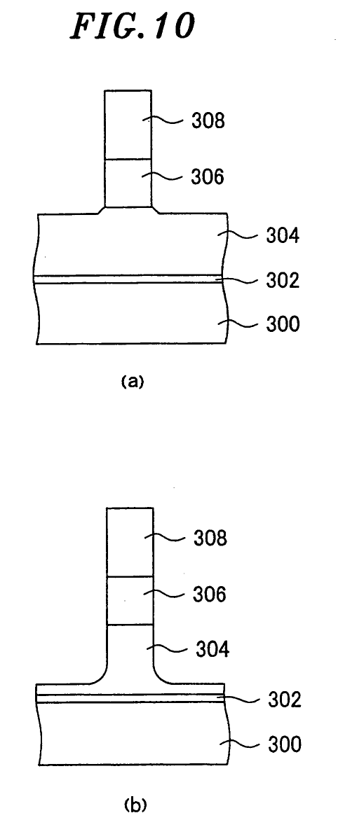

After that, a native oxide film on an exposed portion of the polysilicon film 304 is then etched and removed by using the antireflection film 306 and resist film 308 as the mask under a mixed gas, containing at least CF₄ and O₂ (BT (break through) etching step). An example of a condition for the break through etching step is that pressure in the processing vessel 102 is 10 mTorr, the gap between the upper and the lower electrode 122 and 106 is 85 mm, a flow rate ratio of CF₄ to O₂ (a flow rate of CF₄/a flow rate of O₂) is 67 sccm/13 sccm, the voltage applied to the electrostatic chuck for drawing the wafer is 1.5 kV, pressures of the cooling gas applied to the edge and the center of the backside of the wafer are both 3 mTorr, temperatures of the lower and the upper electrode in the processing chamber 104 are 70° C. and 80° C., respectively, and the temperature of the sidewall of the processing chamber 104 is 60° C. And, the high frequency power applied to the upper electrode 122 is set to be 350 W, the high frequency power applied to the lower electrode 106 is set to be 75 W, and the layered structure is treated by a plasma for about 5.0 sec. Thereby, the native oxide film on the exposed portion of the polysilicon film 304 is removed as shown in FIG. 10(a).

Subsequently, there is conducted a main etching step wherein the polysilicon film layer 304 is etched in the depth direction of openings of the mask pattern. In this step, the polysilicon film 304 is etched in the depth direction of the openings of the mask pattern by using a mixed gas, containing at least HBr and O₂, as a processing gas, to a level where the gate oxide film 302 is not exposed, for example, until a portion of the polysilicon film 304 is etched by 85% of a total thickness of the polysilicon film 304 (ME1: first main etching step). Since the gate oxide film 302 is not yet exposed in the first main etching step, it is etched in a condition suitable to increase an etching rate of the polysilicon film 204.

An example of a condition for the first main etching step is that pressure in the processing vessel 102 is 50 mTorr, the gap between the upper and the lower electrode 122 and 106 is 100 mm, a flow rate ratio of HBr to Cl₂ (a flow rate of HBr/a flow rate of Cl₂) is 350 sccm/50 sccm, the voltage applied to the electrostatic chuck for drawing the wafer is 1.5 kV, pressures of the cooling gas applied to the edge and the center of the backside of the wafer are both 3 mTorr, the temperatures of the lower and the upper electrode in the processing chamber 104 are 70° C. and 80° C., respectively, and the temperature of the sidewall of the processing chamber 104 is 60° C. And, the high frequency power applied to the upper electrode 122 is set to be 700 W, the high frequency power applied to the lower electrode 106 is set to be 75 W, and the layered structure is treated by a plasma for about 45.0 sec. Thereby, the portion of the polysilicon film 304 is etched in the depth direction of the openings of the mask pattern by about 85% of an initial thickness of the polysilicon film 304 as shown in FIG. 10(b). An end point of the first main etching step may be determined by the same procedure as in the case of the first embodiment of the present invention.

Next, there is conducted a second main etching step (ME2) for removing residual parts of the polysilicon film layer 304. In the second main etching step, the polysilicon film 304 is etched by using a mixed gas, containing at least HBr, as a processing gas until the gate oxide film 302 is exposed. An end point of the second main etching step may be determined by the same procedure as in the case of the first embodiment of the present invention.

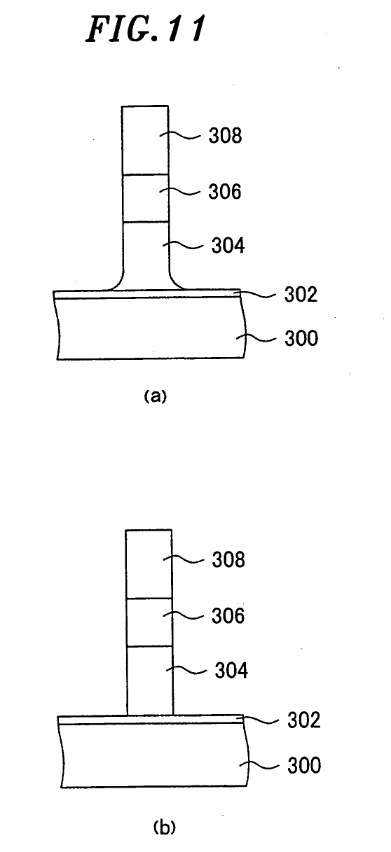

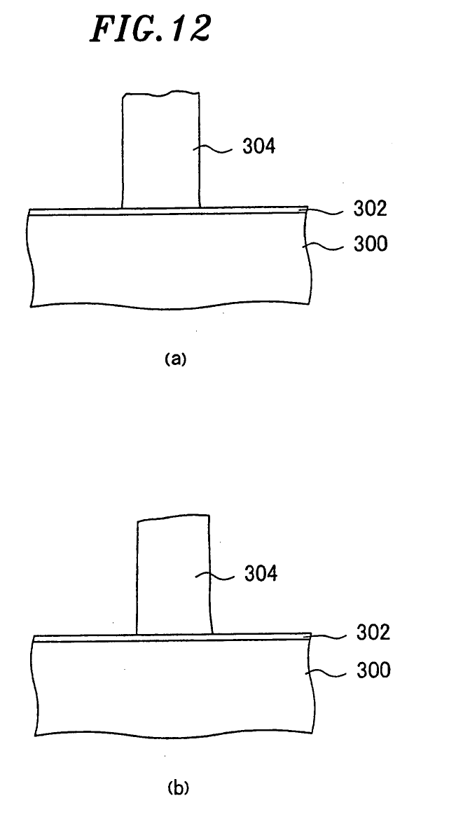

An example of a condition for the second main etching step is that pressure in the processing vessel 102 is 60 mTorr, the gap between the upper and the lower electrode 122 and 106 is 90 mm, a flow rate of HBr is 300 sccm, the voltage applied to the electrostatic chuck for drawing the wafer is 1.5 kV, pressures of the cooling gas applied to the edge and the center of the backside of the wafer are both 10 mTorr, the temperatures of the lower and the upper electrode in the processing chamber 104 are 70° C. and 80° C., respectively, and the temperature of the sidewall of the processing chamber 104 is 60° C. In this step, the high frequency power is applied to the upper and the lower electrode 122, 106 to increase an etching rate of residual parts of the polysilicon film 304. For example, the high frequency power applied to the upper electrode 122 is set to be 150 W, the high frequency power applied to the lower electrode 106 is set to be 20 W, and the layered structure is treated by a plasma for about 25.0 sec. Thereby, the polysilicon film 304 is etched until the gate oxide film 302 is exposed, as shown in FIG. 11(a).

Subsequently, residual parts (i.e. a tapered portion around a lower part of a gate) of the polysilicon film 304 are etched by using a mixed gas, containing at least HBr and O₂, as a processing gas (OE; overetching step).

Since the mixed gas, containing O₂ or HBr, is used as the processing gas so as to improve a selectivity of the polysilicon film 304 to the gate oxide film 302 (a ratio of an etching rate of the polysilicon film 304 to an etching rate of the gate oxide film 302) in the overetching step, a relatively large amount of reaction products is generated during the overetching step. Unlike the first embodiment, in which the oxide film is used as the mask pattern, the resist film is used as the mask pattern in the second embodiment, resulting in a larger amount of reaction products. As a result, there is a stronger possibility that the reaction products are deposited on the wafer to form the tapered portion around the lower part of the gate in comparison with the case of the first embodiment, and thus, it is difficult to improve an anisotropy in the profile.

Accordingly, in order to prevent the tapered portion from being formed around the lower part of the gate to the utmost while enhancing the selectivity, it is necessary to reduce the amount of the reaction products to prevent the reaction products from being deposited on the wafer to the utmost during the overetching step.

As a result of repeated experiments, the present inventors have found that the selectivity of the polysilicon film 304 to the gate oxide film 302 (the ratio of the etching rate of the polysilicon film 304 to the etching rate of the gate oxide film 302) is improved while at the same time reducing the amount of the reaction products to prevent the reaction products from being deposited on the wafer to the utmost by setting the high frequency power applied to the upper electrode 122 to a specific power level or lower during the overetching step after the completion of the second main etching step, due to the same reason as in the first embodiment.

Based on the above description, the overetching step is conducted. An example of a condition for the overetching step is that pressure in the processing vessel 102 is 20 mTorr, the gap between the upper and the lower electrode 122 and 106 is 150 mm, a flow rate ratio of HBr to O₂ (a flow rate of HBr/a flow rate of O₂) is 26 sccm/4 sccm, the voltage applied to the electrostatic chuck for drawing the wafer is 1.5 kV, pressures of the cooling gas applied to the edge and the center of the backside of the wafer are both 10 mTorr, the temperatures of the lower and the upper electrode in the processing chamber 104 are 70° C. and 80° C., respectively, and the temperature of the sidewall of the processing chamber 104 is 60° C.

And, the high frequency power of 100 W is applied to the lower electrode 106 as in the case of the second main etching step. In contrast, the high frequency power applied to the upper electrode 122 is reduced at a time to a specific power level, the specific power level being lower than the high frequency power of the second main etching step. Thereby, it is treated by a plasma for about 30.0 sec.

The high frequency power applied to the upper electrode 122 is set so as to prevent the reaction products, generated in the course of etching the polysilicon film 304, from being deposited on the wafer, preferably 50 W or lower, more preferably 0 W. Thereby, residual parts (tapered portion around the lower part of the gate) of the polysilicon film 304 are etched and a gate electrode with the excellent anisotropic profile thereof is formed as shown in FIG. 11(b). In this step, if the high frequency power applied to the lower electrode 106 is very high, the oxide film may be damaged. For this reason, it is preferable that the high frequency power applied to the lower electrode 106 be 0.4 W/cm² or lower.

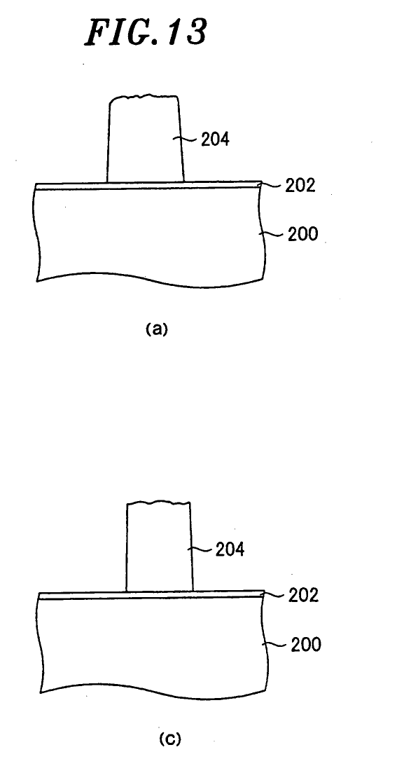

FIG. 12 illustrates an etched object in case that it is etched without the high frequency power being applied to the upper electrode 122 in the overetching step. FIG. 12(a) illustrates the etched object when the gate is formed on the center of the wafer, and FIG. 12(b) illustrates the etched object when the gate is formed on the edge of the wafer. As shown in FIG. 12, there are no tapered portions remained around lower parts of gates formed on the center and edge of the wafer.

As describe above, after the second main etching step, the high frequency power applied to the upper electrode 122 is reduced at a time to 0.16 W/cm² or lower, preferably 0 W/cm², lower than the high frequency power of the second main etching step. Thereby, increasing the selectivity of the polysilicon film 304 to the gate oxide film 302 (the ratio of the etching rate of the polysilicon film 304 to the etching rate of the gate oxide film 302), while at the same time preventing the reaction products, generated in the course of etching the polysilicon film 304, from being deposited on the wafer to the utmost (deposition-less state) Hence, the gate is formed on the wafer without the tapered portion of the polysilicon film 304 remaining around the lower part thereof to the utmost. Therefore, the selectivity as well as the anisotropy in the profile of the gate is simultaneously improved (for example, the gate has a pattern with a wall perpendicular to an upper surface of the gate oxide film 302) in the second embodiment of the present invention.

And, unlike the first embodiment, in which the oxide film is used as the mask, the antireflection film 306 and resist film 308 are used as the mask in the second embodiment, resulting in a larger amount of reaction products than the first embodiment. Hence, it is more effective in case of the second embodiment to reduce the amount of the reaction products to prevent the reaction products from being deposited on the wafer to the utmost (deposition-less state) in comparison with the case of the first embodiment. Particularly, even greater effect can be produced since the high frequency power applied to the upper electrode 122 at a time to 50 W or lower, preferably 0 W in the overetching step in which the amount of the reaction products is greatest.

Hereinafter, a description will be given for the third embodiment of the present invention, referring to the drawings. Here, an etching is conducted by lowering the high frequency power applied to the upper electrode 122 down to a specific power level throughout a middle of a main etching step and an overetching step.

A layered structure used in the third embodiment is the same as that of the first embodiment. The layered structure in FIG. 2(a) is etched in such a manner that a native oxide film on an exposed portion of a polysilicon film 204 is firstly etched to be removed (BT (break through) etching step). An example of a condition for the break through etching step is that pressure in the processing vessel 102 is 10 mTorr, the gap between the upper and the lower electrode 122 and 106 is 80 mm, a flow rate ratio of CF₄ to O₂ (a flow rate of CF₄/a flow rate of O₂) is 67 sccm/13 sccm, the voltage applied to the electrostatic chuck for drawing the wafer is 1.5 kV, pressures of a cooling gas applied to an edge and a center of the backside of the wafer are both 3 mTorr, temperatures of the lower and the upper electrode in the processing chamber 104 are 60° C. and 80° C., respectively, and the temperature of the sidewall of the processing chamber 104 is 60° C.

And, the high frequency powers applied to the upper and the lower electrode 122, 106 are high. For example, the high frequency power applied to the upper electrode 122 is set to be 650 W, and the high frequency power applied to the lower electrode 106 is set to be 220 W. Thereby, the native oxide film on the exposed portion of the polysilicon film 204 is removed, as shown in FIG. 2(b).

Next, a first main etching step corresponding to the first main etching step of the first embodiment is carried out. In the first main etching step, the polysilicon film 204 is etched in a depth direction of openings of a mask pattern by using a mixed gas, containing at least HBr and O₂, as a processing gas, to a level where a gate oxide film 202 is not exposed, for example, until the polysilicon film 204 is etched by 85% of a total thickness of the polysilicon film 204. Since the gate oxide film 202 is not yet exposed in the first main etching step, it is etched in a condition suitable to increase an etching rate of the polysilicon film 204.

An example of a condition for the first main etching step is that pressure in the processing vessel 102 is 30 mTorr, the gap between the upper and the lower electrode 122 and 106 is 120 mm, a flow rate ratio of HBr to O₂ (a flow rate of HBr/a flow rate of O₂) is 400 sccm/3 sccm, the voltage applied to the electrostatic chuck for drawing the wafer is 1.5 kV, pressures of the cooling gas applied to the edge and the center of the backside of the wafer are both 3 mTorr, the temperatures of the lower and the upper electrode in the processing chamber 104 are 60° C. and 80° C., respectively, and the temperature of the sidewall of the processing chamber 104 is 60° C.

And, the high frequency powers applied to the upper and the lower electrode 122, 106 are high. For example, the high frequency power applied to the upper electrode 122 is set to be 100 W, and the high frequency power applied to the lower electrode 106 is set to be 75 W. Thereby, the polysilicon film 204 is etched in a area of openings of the mask pattern by 85% of an initial thickness of the polysilicon film 204 as shown in FIG. 2(c). An end point of the first main etching step may be determined by the same procedure as in the case of the first embodiment.

Subsequently, there is conducted an etching step wherein residual parts of the polysilicon film layer 204 are completely etched by using a mixed gas, containing at least HBr, O₂, He, as a processing gas by reducing the high frequency power applied to the upper electrode 122 to the specific power level or lower. In other words, an etching step, corresponding to the second main etching step (ME2) and the overetching step (OE) of the first embodiment, is conducted under a same condition.

Here, the high frequency power applied to the upper electrode 122 is preferably set to be 0.16 W/cm² or lower (i.e. about 50 W or lower in the case of etching the wafer with a diameter of 200 mm), and more preferably 0 W/cm². In such a case, if the high frequency power applied to the lower electrode 106 is set to be too high, the oxide film may be damaged. For this reason, it is preferable that the high frequency power applied to the lower electrode 106 is set to 0.4 W/cm² or lower (i.e. about 150 W or lower in the case of etching the wafer with the diameter of 200 mm).

An example of a condition for etching the polysilicon film 204 is that pressure in the processing vessel 102 is 60 mTorr, the gap between the upper and the lower electrode 122 and 106 is 120 mm, a flow rate ratio of HBr/O₂/He (a flow rate of HBr/a flow rate of O₂/a flow rate of He) is 400 sccm/8 sccm/500 sccm, the voltage applied to the electrostatic chuck for drawing the wafer is 1.5 kV, pressures of the cooling gas applied to the edge and the center of the backside of the wafer are both 10 mTorr, the temperatures of the lower and the upper electrode in the processing chamber 104 are 60° C. and 80° C., respectively, and the temperature of the sidewall of the processing chamber 104 is 60° C.

And, the high frequency electrical power of 100 W is applied to the lower electrode 106. In contrast, the high frequency electrical power applied to the upper electrode 122 is set to be 0 W, to be reduced at a time so as to be lower than the high frequency power applied to the upper electrode 122 in the first main etching step.

Thereby, residual parts of the polysilicon film 204 are completely etched and a gate electrode with the excellent anisotropic profile thereof (e.g. the gate electrode with a pattern perpendicular to an upper surface of the gate oxide film) is formed as shown in FIG. 3(b).

FIG. 13 illustrates an etched object in case when it is etched without the high frequency power being applied to the upper electrode 122 in the second main etching step and the overetching step. FIG. 13(a) illustrates an etched object when the gate is formed on the center of the wafer, and FIG. 13(b) illustrates the etched object when the gate is formed on the edge of the wafer. As shown in FIG. 13, there are no tapered portions of the polysilicon film 204 remained around lower parts of gates formed on the center and edge of the wafer.

As described above, even if an etching step, corresponding to the second main etching step and the overetching step of the first embodiment, is conducted under a same condition by reducing the high frequency power applied to the upper electrode 122 at a time, the selectivity and the anisotropy in the profile of the gate can be improved while the gate oxide film is not damaged.

The preferred embodiments in accordance with the present invention have been described above. But, the present invention is not limited to the described preferred embodiments. Many modifications and variations of the present invention within the scope of the appended claims are possible in light of the above teachings. And, it is to be understood without doubt that the modifications and variations are within the technical scope of the present invention.

For example, the gate oxide film used as an insulating film layer in the first to third embodiments of the present invention may be exemplified by a Th-Oxide film formed of a thermal oxide film, a CVD (chemical vapor deposition) film produced by CVD, an SOG (spin on glass) film produced by SOG in which a liquid glass is coated on the entire surface of a wafer by using a centrifugal force, or a different type of thermal oxide film.

Further, in the first to third embodiments, a polysilicon film layer, acting as a film layer to be processed on the insulating film layer, is etched by using an oxide film as a mask. However, the present invention is not limited to this. The film layer to be processed may be other type of silicon-based film layer, such as a polycrystalline silicon, a polycide film layer, and a single crystalline silicon film layer. And, it can be applied to etch a metal layer, acting as the film layer to be processed on the insulating film layer, by using the oxide film as the mask.

And, the high frequency power applied to the upper electrode 122 may be reduced at a time in the middle of the main etching step like the first embodiment, in the overetching step like the second embodiment, and during a period ranging from a middle of the main etching step to the overetching step like the third embodiment.

As described above, in accordance with the present invention, for a plasma processing apparatus including an upper and a lower electrode, anisotropy in the profile (e.g. a gate electrode has a pattern with a wall perpendicular to a surface of a substrate to be processed) can be improved while enhancing the selectivity of etching, and total etching rate can be prevented from being lowered by reducing the high frequency power applied to the upper electrode to a specific power level or lower during an etching step.

While the invention has been shown and described with respect to the preferred embodiments, it will be understood by those skilled in the art that various changes and modifications may be made without departing from the spirit and scope of the invention as defined in the following claims.

### INDUSTRIAL APPLICABILITY

The present invention can be applied to an etching method, more particularly to an etching method using a plasma processing apparatus provided with an upper and a lower electrode facing each other and allowing high frequency powers to be applied to the upper and the lower electrode.

1. An etching method for plasma etching a film layer to be processed formed on an object to be processed by introducing a processing gas into an airtight processing chamber by using a plasma processing apparatus provided with an upper and a lower electrode facing each other in the processing chamber and allowing high frequency powers to be applied to the upper and the lower electrode,
wherein while plasma etching the film layer to be processed by applying the high frequency powers to the upper and the lower electrode, a high frequency power applied to the upper electrode is set to be a specific power level or lower.

2. The etching method of claim 1, wherein the film layer to be processed resides on an insulating film layer formed on the object to be processed.

3. The etching method of claim 2, wherein while plasma etching the film layer to be processed, the high frequency power applied to the upper electrode is set to be 0.16 W/cm² or lower.

4. The etching method of claim 3, wherein the high frequency power applied to the lower electrode is set to be 0.4 W/cm² or lower.

5. The etching method of claim 2, wherein while plasma etching the film layer to be processed, the high frequency power applied to the upper electrode is set to be 0 W/cm².

6. The etching method of claim 2, comprising:
a main etching step for etching the film layer to be processed in a depth direction of openings of a mask pattern serving as a mask by applying the high frequency powers to the upper and the lower electrode; and
an overetching step for removing, after the main etching step, residual parts of the film layer to be processed,
wherein during the main etching step, the high frequency power applied to the upper electrode is lowered down to the specific power level or lower, and the film layer to be processed is etched until a part of the insulating film layer is exposed.

7. The etching method of claim 6, wherein the main etching step includes:
a first main etching step for etching the film layer to be processed down to a level where the insulating film layer is not exposed; and
a second main etching step for etching, after the first main etching step, the film layer to be processed until the part of the insulating film layer is exposed by lowering the high frequency power applied to the upper electrode down to the specific power level or lower, the specific power level being lower than a power level of the first main etching step.

8. The etching method of claim 6, wherein the high frequency power applied to the upper electrode is set to be 0.16 W/cm² or lower in the second main etching step.

9. The etching method of claim 8, wherein a high frequency power applied to the lower electrode is set to be 0.4 W/cm² or lower in the second main etching step.

10. The etching method of claim 6, wherein the high frequency power applied to the upper electrode is set to be 0 W/cm² in the second main etching step.

11. The etching method of claim 2, comprising:
a main etching step for etching, by applying the high frequency powers to the upper and the lower electrode, the film layer to be processed in a depth direction of openings of a mask pattern serving as a mask until a part of the insulating film layer is exposed; and
an overetching step for removing, after the main etching step, residual parts of the film layer to be processed,
wherein in the overetching step, the residual parts of the film layer to be processed are etched by lowering the high frequency power applied to the upper electrode down to the specific power level or lower.

12. The etching method of claim 11, wherein the high frequency power applied to the upper electrode is set to be 0.16 W/cm² or lower in the overetching step.

13. The etching method of claim 12, wherein a high frequency power applied to the lower electrode is set to be 0.4 W/cm² or lower in the overetching step.

14. The etching method of claim 11, wherein the high frequency power applied to the upper electrode is set to be 0 W/cm² in the overetching step.

15. The etching method of claim 2, comprising:
a main etching step for etching, by applying the high frequency powers to the upper and the lower electrode, the film layer to be processed in a depth direction of openings of a mask pattern serving as a mask until a part of the insulating film layer is exposed; and
an overetching step for removing, after the main etching step, residual parts of the film layer to be processed,
wherein in any one or both of the main etching step and the overetching step, the film layer to be processed is etched by lowering the high frequency power applied to the upper electrode down to the specific power level or lower.

16. The etching method of claim 2, comprising:
a first main etching step for etching the film layer to be processed in a depth direction of openings of a mask pattern serving as a mask by applying the high frequency powers to the upper and the lower electrode, to a level where the insulating film layer is not exposed;
a second main etching step for etching, after the first main etching step, the film layer to be processed until a part of the insulating film layer is exposed; and
an overetching step for removing residual parts of the film layer to be processed,
wherein the film layer to be processed is etched by lowering the high frequency power applied to the upper electrode down to the specific power level or below throughout the second main etching step to the overetching step.

17. The etching method of claim 16, wherein the high frequency power applied to the upper electrode is set to be 0.16 W/cm² or lower throughout the middle of the main etching step to the overetching step.

18. The etching method of claim 17, wherein the high frequency power applied to the lower electrode is set to be 0.4 W/cm² or lower throughout the middle of the main etching step to the overetching step.

19. The etching method of claim 18, wherein the high frequency power applied to the upper electrode is set to be 0 W/cm² throughout the middle of the main etching step to the overetching step.
